(19) United States
(12) Patent Application Publication
(10) Pub. No.: US 2011/0072333 A1
(43) Pub. Date: Mar. 24, 2011

(54) CONTROL METHOD FOR FLASH MEMORY BASED ON VARIABLE LENGTH ECC

(75) Inventor: Lung-Yi KUO, Jhubei City (TW)

(73) Assignee: INNOSTOR TECHNOLOGY CORPORATION, Hsinchu City (TW)

(21) Appl. No.: 12/566,627

(22) Filed: Sep. 24, 2009

(51) Int. Cl. G11C 29/04; H03M 13/00; G06F 12/00; G06F 11/08

(52) U.S. Cl. 714/773; 714/752; 711/103; 714/E11.03; 711/E12.001; 711/E12.008

(57) ABSTRACT

A control method for flash memory based on variable length ECC is provided in the present invention. A first channel of the flash memory is set to have a first ECC with a first length based on the size of data page and the length of first management data; and a second channel of the flash memory is set to have a second ECC with a second length based on the size of data page and the length of second management data. The first ECC and the second ECC are designated with different identification codes respectively, wherein the first length is shorter than the second length.

### BACKGROUND OF THE INVENTION

1. Field of the Invention

The present invention relates to a control technique for a flash memory, and more particularly to a control method for flash memory using variable length error correction codes (ECCs), wherein ECCs of different lengths are designated to different channels to improve ability of error correcting.

2. Description of Related Art

Flash memory has the structure similar to that of EEPROM (Electrically Erasable Programmable Read-Only Memory) and may occur possible errors caused by semiconductor fabricating process. Therefore, flash memory relies on error correction codes (ECC) to correct the presence of errors.

The error correcting ability and the space for storing management stored of the flash memory are depended on the length of ECC. In the prior art, the flash memory utilizes the ECC of an acceptable constant length to correct errors. Therefore, all data pages of the flash memory have the equal error correcting ability.

With reference to FIG. 4, the ECC determined by the BCH (Bose, Ray-Chaudhuri, Hocquenghem) theory is able to correct 8 bits error existing in the data area and has a size of 13 bytes.

Generally, a flash memory controller adopting the ECC of constant length is unable to fully utilize a large data page-based flash memory, such as the 8K data page.

To overcome the shortcomings, the present invention provides a control method for a flash memory based on variable length ECC to mitigate or obviate the aforementioned problems.

### SUMMARY OF THE INVENTION

An objective of the present invention is to provide a control method for a flash memory based on variable length error correction codes (ECCs), wherein ECCs of different lengths are designated to different channels to increase ability of error correcting.

The method in accordance with the present invention has the steps of:

pre-defining a first ECC with a first length for a first channel according to a data page size and a first management data of the flash memory;

pre-defining a second ECC with a second length for a second channel of according to the data page size and a second management data of the flash memory;

determining whether a target channel to be accessed is the first channel;

setting an ECC for the first channel to have the first length when the target channel to be accessed is the first channel; and

setting an ECC for the second channel to have the second length when the target channel to be accessed is not the first channel.

In comparison to the ECCs with constant length for all channels, the present invention designates different ECCs with different lengths for different channels based on the data page size. Therefore, the purpose of providing higher data accessing correctness of the flash memory is achieved.

Other objectives, advantages and novel features of the invention will become more apparent from the following detailed description when taken in conjunction with the accompanying drawings.

### BRIEF DESCRIPTION OF THE DRAWINGS

FIG. 1 illustrates ECCs and management data in different channels of a flash memory with a data page size of 2048 bytes (2K) in accordance with the present invention;

FIG. 2 illustrates ECCs and management data in different channels of a flash memory with a data page size of 4096 bytes (4K) in accordance with the present invention;

FIG. 3 illustrates a flow chart of a flash memory controller setting ECC in accordance with the present invention;

FIG. 4 illustrates ECCs and management data in different channels of a flash memory with a data page size of 4096 bytes (4K) in accordance with prior art.

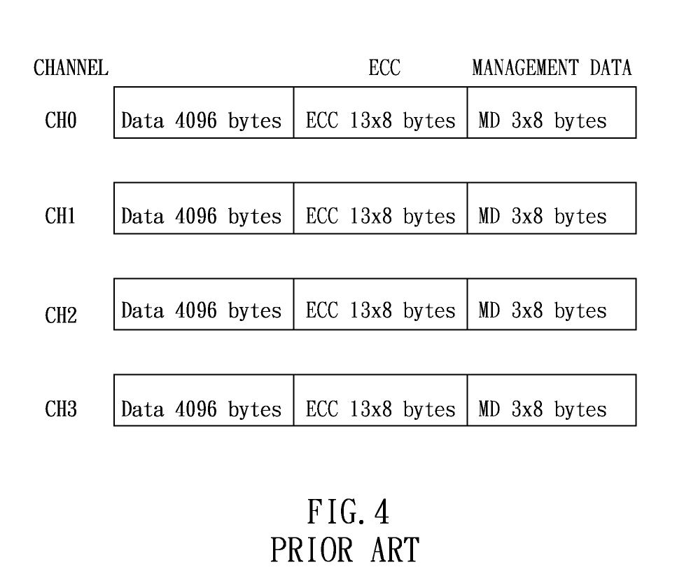

### DETAILED DESCRIPTION OF PREFERRED EMBODIMENT

NAND flash memory is consisted of multiple data pages, and each data page has a data zone and a spare zone. Therefore, each data page has a size of (512+16)×N and N is the number of sectors. For example, N is 4 for the data page size of 2048 bytes (2K), and N is 8 for the data page size of 4096 bytes (4K). For most of flash memories, the data pages are typically 512 or 2048, 4096 or 8192 bytes in size, and a block is consisted of 64 or 128 data pages.

Different blocks or different channels of the flash memories may require different space size for storing management data. Typically, a data page with 2048 bytes has a spare zone of 16×4=64 bytes in size to store ECC and management data. If the flash memory has ability to correct 8 bits error based on the BCH (Bose, Ray-Chaudhuri, Hocquenghem) theory, the error correction codes (ECC) occupies 13×4=52 bytes in the spare zone, only remaining 64−52=12 bytes for storing the management data.

The control method for the flash memory based on variable length error correction codes (ECCs) comprises the steps of

pre-defining a first ECC with a first length for a first channel according to a data page size and a first management data of the flash memory;

pre-defining a second ECC with a second length for a second channel of according to the data page size and a second management data of the flash memory;

determining whether a target channel to be accessed is the first channel;

setting an ECC for the first channel to have the first length when the target channel to be accessed is the first channel; and

setting an ECC for the first channel to have the second length when the target channel to be accessed is not the first channel.

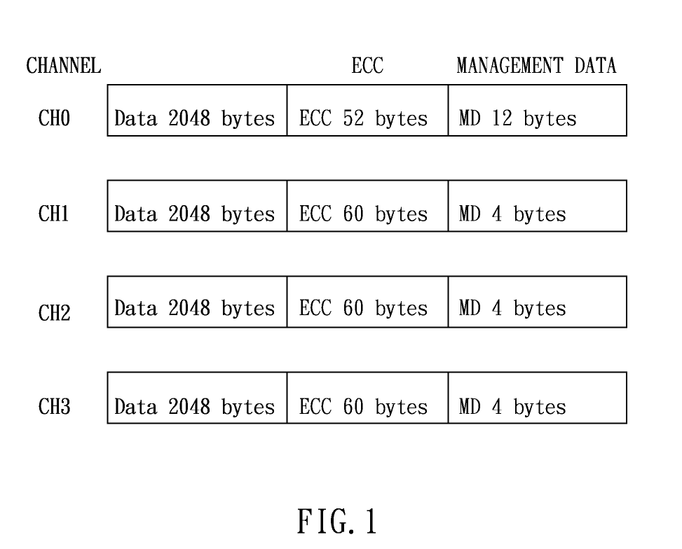

With reference to FIG. 1, taking the data page size of 2048 bytes as an example, when a flash memory controller manages the flash memory, complete management data is stored in a first channel, channel 0, so that the flash memory controller can retrieve all necessary management data at one time. Therefore, the size of ECC is defined as 52 bytes and the size of the management data is 12 bytes in the channel 0. Management data in any remaining channel other than the channel 0 is reduced to 4 bytes. Therefore, the space for storing ECC can be increased to 64−4=60 bytes and a longer ECC is available.

In accordance with the present invention, the channel 0 and other channels are provided with different ECCs and management data with different lengths. Therefore, the majority of channels can obtain ECC with more bytes to enhance the error correcting ability.

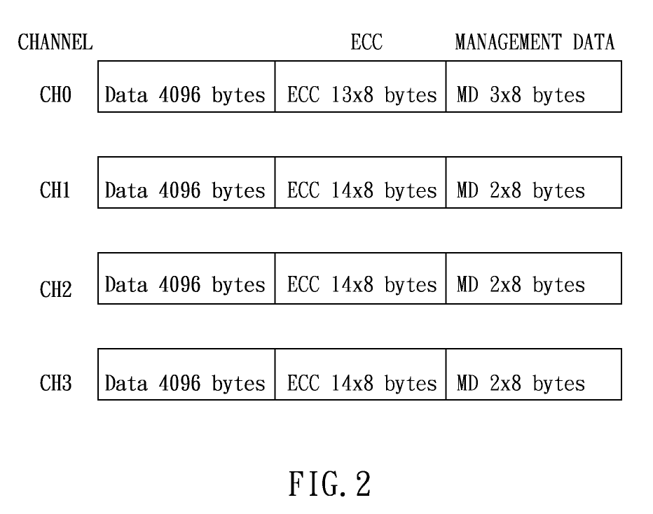

With reference to FIG. 2, when the present invention is applied to the flash memory with the data page size of 4096 bytes, the management data is 3×8 bytes and ECC is 13×8 bytes in the channel 0. The management data in any channels other than the channel 0 is 2×8 bytes in size, and the ECC is increased to 14×8 bytes.

To distinguish the ECCs of different lengths in different channels, the ECC itself may include an identification code located at a fixed position. Preferably, the identification codes is located at the first byte or the last byte of the ECC.

A setting rule may be applied to the flash memory to quickly determine the error correcting abilities of different channels in different blocks. For example, the blocks of the flash memory can be categorized as data blocks, temp blocks and information blocks. Each kind of the blocks is designated with the identification code. The data block is further categorized as a channel 0 and other channels. The channel 0 and other channels are respectively designated with two types of ECCs, ECC0 and ECC1.

ECC0 is designated to the temp blocks, the channel 0 of each data block and information blocks

ECC1 is designated to other channels other than the channel 0 of each data block. According to the identification codes in the ECCs, the two different types, ECC0 and ECC1, can be easily recognized.

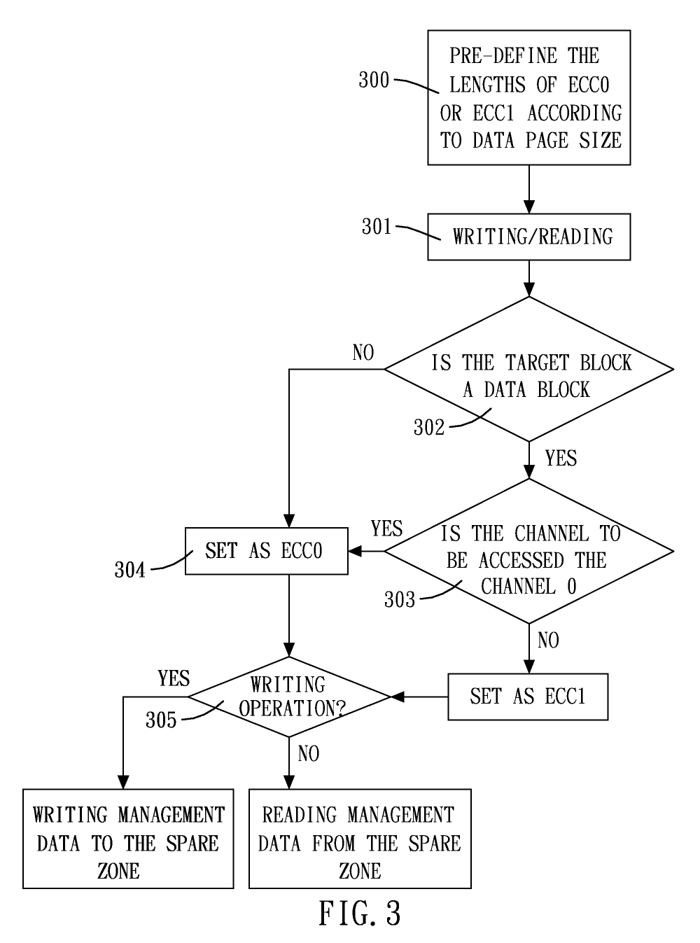

With further reference to FIG. 3, in a practical application, a flash memory controller may determine the ECC according to the following steps before it accesses the flash memory.

First, the lengths of ECC0 and ECC1 are pre-defined based on the data page size and the management data size (step 300). For instance, the ECC0 is 13×8 bytes and ECC1 is 14×8 bytes for the data page size of 4096 bytes.

Subsequently, the flash memory controller starts to access the flash memory. In this embodiment, the flash memory controller performs reading and writing operations (step 301).

The flash memory controller then determines if the target block is a data block (step 302). If the target block is the data block, the next step (step 303) is performed. Otherwise, the flash memory controller performs the step 304.

The flash memory controller then checks if the target channel to be accessed is channel 0 (step 303). If the target channel is the channel 0, the ECC is set as ECC0 (step 304). Otherwise, the ECC is set as ECC1.

The flash memory controller finally checks if the operation to be performed is a writing operation (step 305). If the operation to be performed is the writing operation, the flash memory controller writes management data corresponding to ECC0 or ECC1 to the spare zone. Otherwise, the flash memory controller reads management data from the spare zone and then analyzes the management data according to ECC0 or ECC1.

In conclusion, when the present invention is applied to either the small data page or large data page, superior error correction effect is achieved. In comparison to the conventional ECCs with constant length for all channels, the present invention designates different ECCs with different lengths for different channels based on the data page size. Therefore, high correctness of data accessing of the flash memory can be ensured.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A control method for a flash memory based on variable length error correction codes (ECCs) comprises the steps of
pre-defining a first ECC with a first length for a first channel according to a data page size and a first management data of the flash memory;
pre-defining a second ECC with a second length for a second channel of according to the data page size and a second management data of the flash memory;
determining whether a target channel to be accessed is the first channel;
setting an ECC for the first channel to have the first length when the target channel to be accessed is the first channel; and
setting an ECC for the second channel to have the second length when the target channel to be accessed is not the first channel.

2. The method as claimed in claim 1 further comprising:
setting a first type of blocks and a second type of blocks in the flash memory based on types of data stored in the flash memory;
wherein the first type of blocks is designated with an ECC with the first length.

3. The method as claimed in claim 2, wherein the first channel of the second type of blocks is designated with an ECC with the first length.

4. The method as claimed in claim 3, wherein the second channel of the second type of blocks is designated with an ECC with the second length.

5. The method as claimed in claim 1, further comprising:
providing a first identification code in the first ECC with the first length; and
providing a second identification code in the second ECC with the second length.

6. The method as claimed in claim 5, wherein the first identification code is located in either a first byte or a last byte of the first ECC, and the second identification code is located in either a first byte or a last byte of the second ECC.

7. The method as claimed in claim 1, further comprising:
accessing the first management data from the first channel when the first channel is a target channel to be accessed after the lengths of the ECCs for the first channel and the second channel have been set;
accessing the second management data from the second channel when the second channel is a target channel to be accessed after the lengths of the ECCs for the first channel and the second channel have been set.

8. The method as claimed in claim 1, wherein the second length is longer than the first length.
